(19) United States
(12) Patent Application Publication
(10) Pub. No.: US 2026/0076187 A1
(43) Pub. Date: Mar. 12, 2026

(54) Single Crystal Diamond Dies Packaged with Ultrathin Semiconductor Wafer

(71) Applicant: Diamond Foundry Inc., South San Francisco, CA (US)

(72) Inventors: Martin Roscheisen, San Francisco, CA (US); Jeroen Van Duren, Fremont, CA (US); Liubo Hong, San Jose, CA (US); Michael Shirk, Brentwood, CA (US); Braden Henderson, Mountain View, CA (US)

(21) Appl. No.: 19/297,056

(22) Filed: Aug. 12, 2025

Related U.S. Application Data
(60) Provisional application No. 63/691,630, filed on Sep. 6, 2024.

(51) Int. Cl. H01L 23/373; H01L 23/00

(52) U.S. Cl. CPC H10W 40/254; H10W 40/255; H10W 90/734

(57) ABSTRACT

A reconstituted wafer product may include dies containing diamond sandwiched between first and second wafers in a manner that provides a thermally conductive connection between the first wafer and second wafer through the dies containing diamond. Alternatively, dies containing diamond may be attached to a tape in frame or temporary carrier substrate or tape on reel carrier substrate. Alternatively, dies containing diamond may be attached to a wafer in a manner that provides a thermally conductive connection between the wafer and the dies containing diamond. A first smoothening layer may be formed on a first side of the dies between the wafer and the dies. A second smoothening layer may be formed on a second side of the dies with the dies containing sandwiched between the first and second smoothening layers.

### CLAIM OF PRIORITY

This application claims the priority benefit of U.S. Provisional Application No. 63/691,630 filed Sep. 6, 2024, the entire contents of which are incorporated herein by reference.

### CROSS-REFERENCE TO RELATED APPLICATION

This application is related to U.S. Provisional Patent Application No. 63/539,983 to Jeroen K. J. Van Duren and Martin R. Roscheisen, filed Sep. 22, 2023, the entire contents of which are incorporated herein by reference. This application is also related to International Patent Application Number PCT/US23/86169 filed Dec. 28, 2023, the entire contents of which are incorporated herein by reference. International Patent Application Number PCT/US24/30242 is further related to U.S. Provisional Patent Application No. 63/539,983, filed Sep. 22, 2023. This application is related to U.S. patent application Ser. No. 18/761,091, filed Jul. 1, 2024, the entire contents of which are incorporated herein by reference.

### BACKGROUND

It is well known that diamond conducts heat very well and can serve as a heat spreader in electronics devices. This holds for both single crystal and polycrystalline diamond. It is advantageous to integrate a diamond layer between an integrated circuit device and a heat sink in a die stack. The advantage of integrating a layer of diamond, e.g., single crystal diamond (SCD) into a stack with an integrated circuit (IC) semiconductor die is that the diamond layer efficiently spreads the heat generated by the IC die during operation. Such heat spreading reduces the formation of localized “hot spots” that can negatively impact device performance.

Previous patent applications have focused on (1) integrating polished SCD dies into the final customer chip package, (2) “height matching” SCD-based dies with high-bandwidth memory (HBM) in an advanced package by use of a filler material instead of just thick SCD, since thick SCD is costly, and (3) introducing a “smoothening material” or “compliant bond material” to allow for less SCD polishing, since polishing SCD is difficult. Where polishing SCD dies is difficult, polishing large SCD wafers is even more difficult. Yet the infrastructure for semiconductor manufacturing is dominated by wafer processing, e.g. 300 mm diameter silicon wafers for CMOS designed for AI. Processing diamond dies, a foreign (non-silicon) material sized as a small plate instead of a round wafer poses integration challenges. Surprisingly, the thermal impact of the incorporation of an additional thin layer of silicon between a rough diamond and the integrated circuit is minimal on the benefit of the SCD heat spreading where the SCD roughness can even be beneficial.

It is within this context that aspects of the present disclosure arise.

### BRIEF DESCRIPTION OF THE DRAWINGS

FIG. 1 is a side cut-away view of diamond dies sandwiched between a first and second wafer with a gap filler material according to an aspect of the present disclosure.

FIG. 2 is a side cut-away view of diamond dies sandwiched between a first and second wafer with smoothening layers on the diamond dies according to an aspect of the present disclosure.

FIG. 3 is a side cut-away view of diamond dies coupled to a first wafer according to an aspect of the present disclosure.

FIG. 4 is a top-down cut-away view of a reconstituted wafer according to an aspect of the present disclosure.

FIG. 5 is a top-down cut-away view of a reconstituted wafer similar with a through-hole wafer gap filler according to an aspect of the present disclosure.

FIG. 6 is a side cut-away view showing a method for making a reconstituted wafer product with a through hole gap filler wafer according to an aspect of the present disclosure.

FIG. 7 depicts a side cut-away view of a reconstituted wafer with polished diamond dies on a carrier such as a tape in frame according to an aspect of the present disclosure.

FIG. 8 depicts a tape on reel delivery of diamond dies with cover tape according to aspects of the present disclosure.

FIG. 9 depicts another implementation of reconstituted wafer without gap filler according to aspects of the present disclosure.

FIG. 10 shows a reconstituted wafer heat spreader product incorporated into a Chip on Wafer on Substrate (CoWoS) system stack according to an aspect of the present disclosure.

FIG. 11 shows a graph of absorption coefficient and penetration depth as a function of photon energy.

### DETAILED DESCRIPTION

### Introduction

It is often prohibitively expensive or impractical to fabricate an SCD wafer or polycrystalline diamond (PCD) wafer of certain standard semiconductor wafer diameters, such as 300 mm or 450 mm, with semiconductor surface specifications. According to aspects of the present disclosure, it would be desirable to produce a reconstituted wafer having an array of diamond (e.g. SCD or PCD) dies or diamond die stacks that can be shipped to a semiconductor device fabrication plant (sometimes called a “fab” or “foundry”) in a configuration that is compatible with semiconductor processing done by the plant. As used herein, a “reconstituted wafer” refers to a wafer where multiple diamond (e.g. SCD or PCD) dies are placed on a temporary or permanent carrier wafer. There are a number of technical challenges to configuring and fabricating such a reconstituted wafer.

One challenge is to make the die surface smooth enough for bonding and to make the diamond die thickness tolerance tight enough for bonding. In some implementations a smoothening layer or compliant layer may be used between the diamond die and the layers above and/or below it to ensure the desired smoothness and/or thickness tolerance.

Another challenge is that the surface of the diamond die or smoothening material may be incompatible with typical semiconductor fabrication processes. To address such challenges, in some implementations a wafer, e.g., a silicon wafer, may be bonded to the logic-facing surface of the diamond dies or die stacks and thinned, e.g., to <100 μm or <10 μm. The resulting stack may be easily bonded to a semiconductor wafer on which logic elements are formed. Making the wafer that is bonded to the diamond very thin adds little thermal resistance to the overall diamond die stack.

Yet another challenge is that the diamond dies or die stacks are typically placed on an underlying wafer (sometimes called a carrier wafer) with gaps between adjacent dies. Such gaps may present challenges during subsequent processing steps. For example, the gaps may lead to structural support issues if the diamond dies or die stacks are covered by a layer of material that is thinner than the width of the gaps. Furthermore, the gaps may present problems of edge rounding during subsequent surface finishing steps, e.g. during chemical mechanical polishing (CMP). Additionally, the gaps may trap contaminants that are hard to remove. To address such challenges, the gaps may be filled with appropriate gap-filling materials.

According to aspects of the present disclosure, a large diameter (e.g., ≥300 mm diameter) product may be shipped to a fab as a reconstituted wafer, having diamond dies in various forms (e.g., with or without filler, with or without a smoothening layer) temporarily or permanently bonded to one or two wafers, e.g., single crystal silicon (sc-Si). One or both wafers may be thinned prior to shipping the reconstituted wafer to the foundry (fab), and/or thinned at the foundry (fab). Additionally, having an ultrathin silicon wafer (e.g. 10 μm or thinner) sandwiched between the SCD dies and the logic elements adds very minimal thermal resistance to the overall device stack. Similarly, the roughness of the diamond die does not negatively impact the performance of the reconstituted wafer heat spreader product. Shipping a 300 mm product helps with integration in a semiconductor 300 mm foundry (e.g. cleaning, thin film deposition, CMP, bonding), since these fabs typically have the infrastructure and experience to deal with 300 mm wafers but might not have infrastructure and experience to deal with diamond dies.

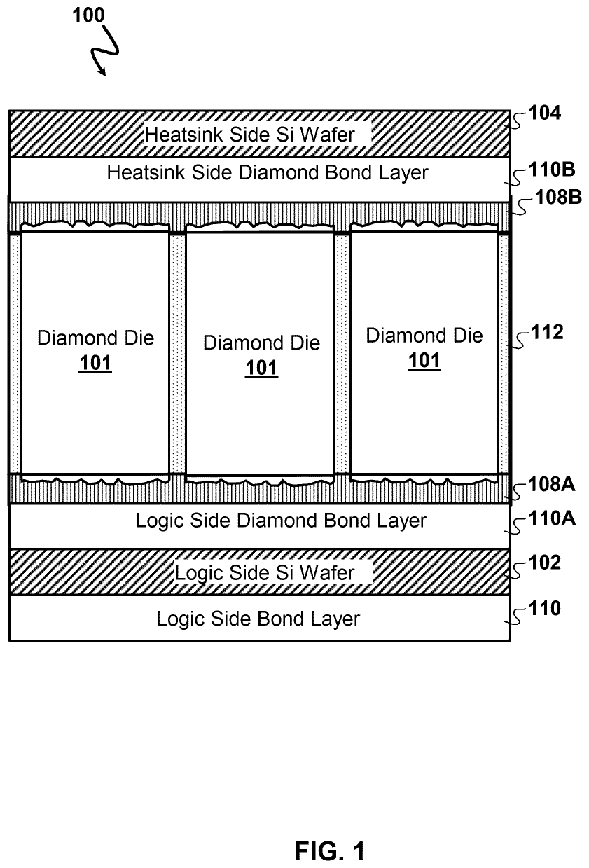

As shown in FIG. 1 one or more dies containing diamond 101, hereinafter diamond dies, may be sandwiched between a first wafer 102 and second wafer 104 to form a reconstituted wafer 100. In the implementation shown, an array of diamond dies having rough top and bottom surfaces may be coated with an adhesion layer. Adhesion layer materials include, for example and without limitation, Titanium, Titanium-carbide, Chromium, and Chromium-Carbide. In some alternative implementations the adhesion layer may be omitted. For example, and without limitation, a smoothening layer such as silicon (e.g., polycrystalline or amorphous) may not require the adhesion layer to be deposited on and may form strong bonds with the diamond dies. The diamond dies 101 are arranged close together and their rough logic-side surfaces are coated with a continuous smoothening layer 108A. Here the smoothening layer partially fills gaps between each of the diamond dies creating a smoothened diamond die assembly. The resulting smoothened diamond die assembly is bonded to the first wafer 102 by a logic-side diamond bond material 110A; here the first wafer 102 is referred to as the logic side wafer, which means that this wafer may be attached to another semiconductor wafer (not shown) on which integrated circuits are formed or will be formed, e.g., using a logic-side bond layer 110. The second wafer 104 is referred to herein as the “heat sink side” wafer, which means that this wafer may be attached to a heatsink, or a wafer on which a heat sink is or will be formed, or a temporary wafer that will be removed prior to introducing the heat sink.

The diamond dies 101, or dies containing diamond, may be single-crystal diamond (SCD), polycrystalline diamond (PCD), or composites of diamond with metals, e.g. a mixture of diamond and copper, or a mixture of diamond and silver, or a mixture of diamond and silicon carbide, or a mixture of diamond and silicon. A mixture might mean a random 3-dimensional distribution of one material in the other material. A mixture might mean an organized 3-dimensional structure of one material in the other material. A mixture might mean a combination of a random and organized distribution of one material in the other material. Similarly, diamond dies may be stacks of diamond with copper, or diamond with silicon carbide, or diamond with silicon, or diamond with aluminum. The diamond dies 101 may be stacks that incorporate adhesion layers, diffusion barriers, smoothening layers, bond layers 110, 110A, 110B, filler materials for height matching in advanced chip packages, or precursors to bond line materials. As used herein the terms diamond die and dies containing diamond may be used interchangeably. In addition to the diamond dies, dummy dies may be placed in the reconstituted wafer product 100 at locations corresponding to the location of logic elements that are not known good dies. This results in a reconstituted wafer product with diamond dies located at the position of known good dies, and dummy dies at the location of logic elements that are not known good dies. Dummy dies may be made out of any suitable thermally conductive material for example and without limitation, silicon. Additionally in some implementations, for stability, dummy dies may be placed in locations in the reconstituted wafer corresponding to empty spaces between the attached logic elements and/or locations that promote structural stability of the reconstituted wafer product. Composites of diamonds may be with copper, silver, gold, aluminum, or zinc.

The thermal resistance of the reconstituted wafer product 100 from the logic side to the heatsink side when integrated into the final chip package may be less than 2000 m²-K/GW (2 mm²-K/W), more preferably less than 1000 m²-K/GW (1 mm²-K/W), even more preferred less than 500 m²-K/GW (0.5 mm²-K/W). It should be noted that the thermal resistance for the shipped product may be higher, since the wafer on the logic side and/or the wafer on the heat sink side may be thinned at the customer (foundry) site prior to or after bonding to the logic elements.

The thermal resistance of the wafers, adhesion layers, diffusion barrier layers, bond layers, smoothening layers, metal foils, diamond dies, or other materials that may be used in the reconstituted wafer product and that may be in the path of heat transport may be designed and/or treated to reduce the thermal resistance. Thermal resistance may be reduced by reducing the thickness of the layer. Thermal resistance may be reduced by increasing the thermal conductivity of the layer, e.g., by selecting higher thermal conductivity materials. Thermal conductivity may be enhanced in each layer by selecting higher purity materials. Thermal conductivity may be enhanced by reducing crystal defects, e.g., vacancies, or interstitials, e.g., by annealing. Thermal conductivity may be enhanced by reducing the number of grain boundaries, e.g., by optimized deposition conditions, or making the material more isotopically pure, e.g. by using isotopically enriched deposition materials. Thermal resistance may be reduced by optimizing the structure of the interface, e.g., the roughness. Thermal resistance may be reduced by optimizing both the thickness and the interface structures of the various layers in the product.

The logic-side wafer 102 may contain silicon (e.g., single crystal silicon) and may be permanently bonded to diamond dies 101. The logic-side wafer may contain silicon (e.g., single crystal silicon) and may be temporarily bonded to the diamond dies. The logic-side wafer may contain glass or sapphire or silicon carbide or polycrystalline diamond and may be temporarily bonded to the diamond dies 101.

By way of example, and not by way of limitation, the heatsink-side wafer 104 may contain silicon (e.g., single crystal silicon) and may be permanently bonded to SCD dies. The heatsink-side wafer 104 may contain silicon (e.g., single crystal silicon) and may be temporarily bonded to the diamond dies 101. The heatsink-side wafer may contain glass or sapphire or silicon carbide or polycrystalline diamond and may be temporarily bonded to the diamond dies 101. The wafer (e.g., single crystal silicon) on the heat sink side may be attached to the diamond dies 101 via thick copper foil.

In other non-limiting example implementations, the reconstituted wafer product 100 may be a permanent stack of a single crystal silicon wafer on the logic side, SCD dies between both wafers, and a single crystal silicon wafer on the heat sink side. The reconstituted wafer may be a permanent stack of a single crystal silicon wafer on the logic side, SCD dies with copper foil facing the heat sink side, and a single crystal silicon wafer on the heat sink side. The reconstituted wafer may be a stack of a permanently bonded single crystal silicon wafer on the logic side, SCD dies with copper foil facing the heat sink side, and a temporarily bonded wafer (carrier) on the heat sink side.

The reconstituted wafer product 100 may have alignment marks or fiducials to aid accurate alignment during bonding to the logic elements. The alignment marks may be on one or both of the outer surfaces of the reconstituted wafers. The alignment marks may be on one or both of the inner wafer surfaces of the reconstituted wafers.

During production the logic-side wafer 102 may act as a carrier having a thickness of greater than 100 micrometers (microns). Later, after assembly, the logic-side wafer may be thinned to less than 100 microns in thickness and in some implementations less than 10 microns in thickness. Before bonding the logic-side wafer 102 may be coated in a bonding layer 110A that is complementary to the smoothening material 108B. For example, and without limitation, if the smoothening material is copper then the bonding layer may also be copper such that the smoothening layer may be used with thermocompression bonding to bond copper on the wafer to copper on the diamond die.

In some implementations, according to aspects of the present disclosure, the locations of each of the diamond dies 101 may correspond to hot spots in logic elements bonded to the logic wafers. In some implementations, according to aspects of the present disclosure, the locations of each of the diamond dies 101 may correspond to the locations of the IC (e.g., logic) die of the targeted IC (e.g., logic) wafer. In some implementations according to aspects of the present disclosure the locations of each of the diamond dies may correspond to the locations of the known good dies (KGD) of the targeted IC (e.g., logic) wafer. In some implementations, according to aspects of the present disclosure, the size of the diamond dies may correspond to the size of the IC (e.g., logic) die of the targeted IC (e.g., logic) wafer. In some implementations, according to aspects of the present disclosure, the size of the diamond dies may be slightly smaller than the size of the IC (logic) die of the targeted IC (e.g., logic) wafer. In some implementations, according to aspects of the present disclosure, the size of the diamond dies 101 may be slightly larger than the size of the IC (e.g., logic) die of the targeted IC (e.g., logic) wafer and partially or completely cover the dicing street width.

The gaps between adjacent diamond dies 101 are fully filled with a gap filling material 112. In some implementations the gap filling material may partially fill the gaps between the diamond dies instead of completely filling them. As discussed below the gap filling material 112 may be a raw or doped silica glass formed by methods such as spin on glass application. Alternatively in some implementations a through-hole wafer may be used as the gap filler. Furthermore, the gap-filling material 112 may contain one or more of the following: a sol-gel, oxide powder, silicon powder, thermoplastic, curable adhesive, molding compound, epoxies, photoresists, benzocyclobutene (BCB) derivatives, spin-on photo-dielectrics, silicones, or polyimides.

A second smoothening layer 108B may be disposed on top of diamond dies and the gap filling material 112. The second smoothening layer herein may be referred to as the heatsink side smoothening layer. A second wafer 104 referred to as the heatsink side wafer may be coated with a heatsink-side diamond bond material 110B that is compatible with the heatsink side smoothening layer 108B. Thus, a reconstituted wafer product 100 may be created having diamond dies 101 sandwich between two wafers 102, 104. This implementation creates a packaged diamond die product that is resistant to breakage and provides for ease of integration in other products.

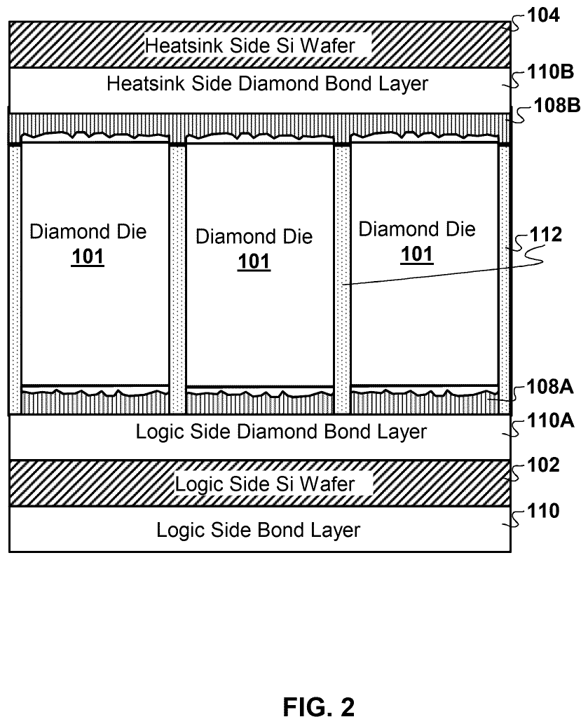

FIG. 2 depicts an alternative implementation of the diamond die package shown in FIG. 1. In this implementation each of the diamond dies is individually coated with a smoothening material 108A. Subsequently each of the diamond dies may be bonded individually with the logic side bond layer on the logic side wafer. As a result, the gap filler material 112 may be deposited in gaps in the smoothening layer 108A between the diamond dies as well as the gaps between each of the diamond dies 101. Additionally in implementations that use a through-hole wafer gap filler the height of the wafer may be selected to accommodate the height of the diamond dies with smoothening layer. This implementation may make it easier to accurately place the diamond dies onto the logic side wafer 102.

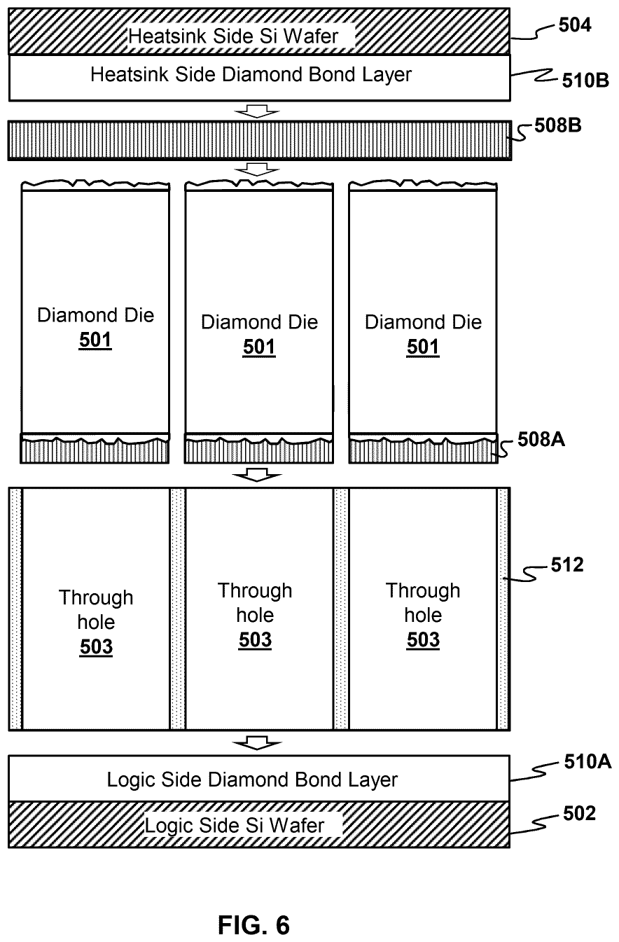

In some implementations, such as those discussed below with respect to FIG. 6, the diamond dies 101 may be inserted into corresponding openings in a through-hole wafer. The material of the through-hole wafer between the openings acts as a gap filler material 112. The diamond dies and through-hole gap filler assembly may be coated in a smoothening layer after the dies have been inserted into the through-holes.

In some implementations, without limitation, SCD dies may be first coated on one or both SCD sides with a smoothening material, e.g., copper, followed by an optional smoothening of one or both top and bottom surfaces, e.g., with CMP, followed by bonding to one of the wafers, e.g., the logic side wafer 102, followed by depositing an optional gap filler 112 and optional planarization of the gap filler, followed by deposition of an optional global smoothening layer 108B (in contrast to a local smoothening layer on each SCD), followed by an optional smoothening of the global smoothening layer, followed by bonding to an optional second wafer, e.g., the heat sink side wafer 104.

In some implementations, without limitation, SCD dies may first be temporarily placed on a temporary carrier, followed by deposition of a gap filler and an optional planarization of the gap filler, coated globally with a smoothening material, e.g., copper, followed by an optional smoothening of the global smoothening material, e.g., with CMP, followed by bonding to one of the wafers, e.g., the logic side wafer, followed by removing the temporary carrier, followed by deposition of a global smoothening layer, followed by an optional smoothening of the global smoothening layer, followed by bonding to an optional second wafer, e.g. the heat sink side wafer.

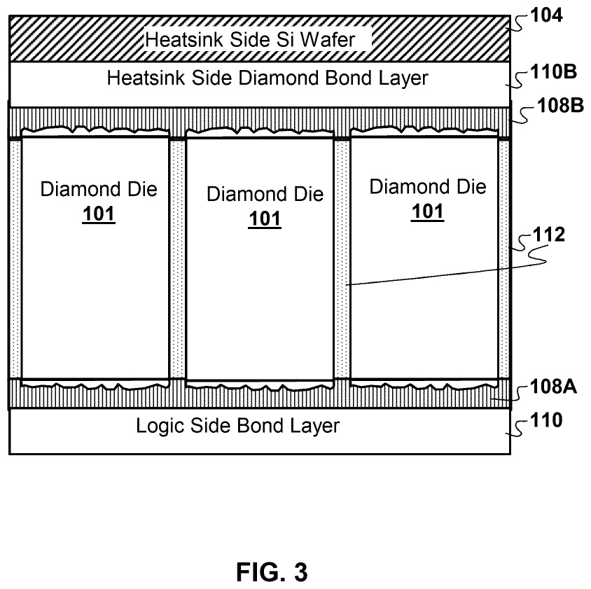

FIG. 3 depicts another alternative implementation of a reconstituted diamond dies wafer 300 according to aspects of the present disclosure. In this implementation the logic side wafer is omitted as compared to FIG. 1. Instead, a bonding layer 110 is directly deposited on the logic-side smoothening layer 108B. This bond layer bonds the reconstituted wafer directly to logic elements (not shown). The material of the bonding layer 110 is chosen to be compatible for bonding methods to the IC wafer as discussed below.

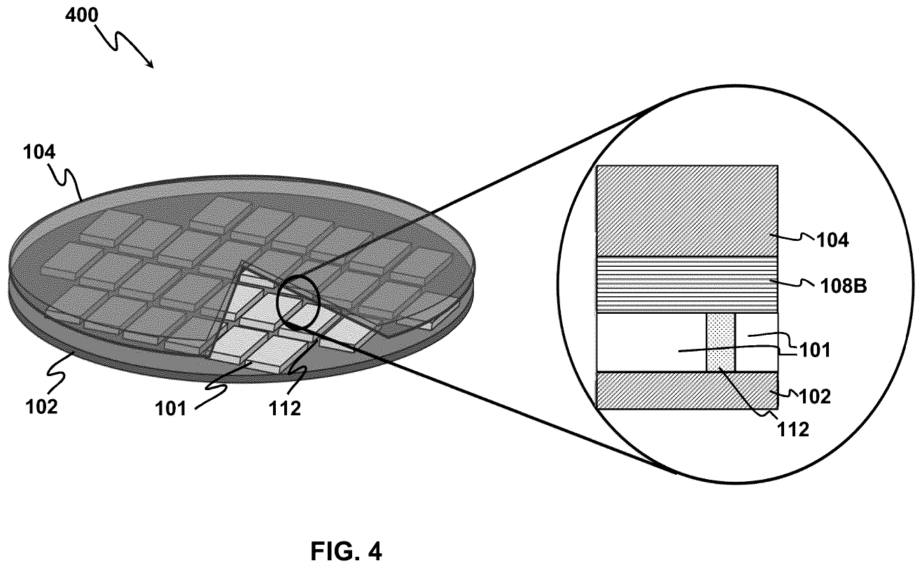

FIG. 4 is a top-down cut-away view of a reconstituted wafer 400 according to an aspect of the present disclosure. In this implementation the diamond dies 101 are disposed on the surface of the logic-side wafer 102. For ease of visualization the heatsink-side wafer 104 has been made to appear semi-transparent. Each of the diamond dies 101 is attached to the logic side wafer, as discussed above. Between each of the diamond dies a gap filling material 112 such as glass has been deposited or otherwise formed. While in this implementation the diamond dies 101 are arranged in a regular pattern on the logic side wafer, aspects of this disclosure are not so limited. For example, and without limitation, the diamond dies 101 may be placed on the logic-side wafer 102 in locations corresponding to one or more hotspots of one or more logic elements which may be coupled to the logic side wafer.

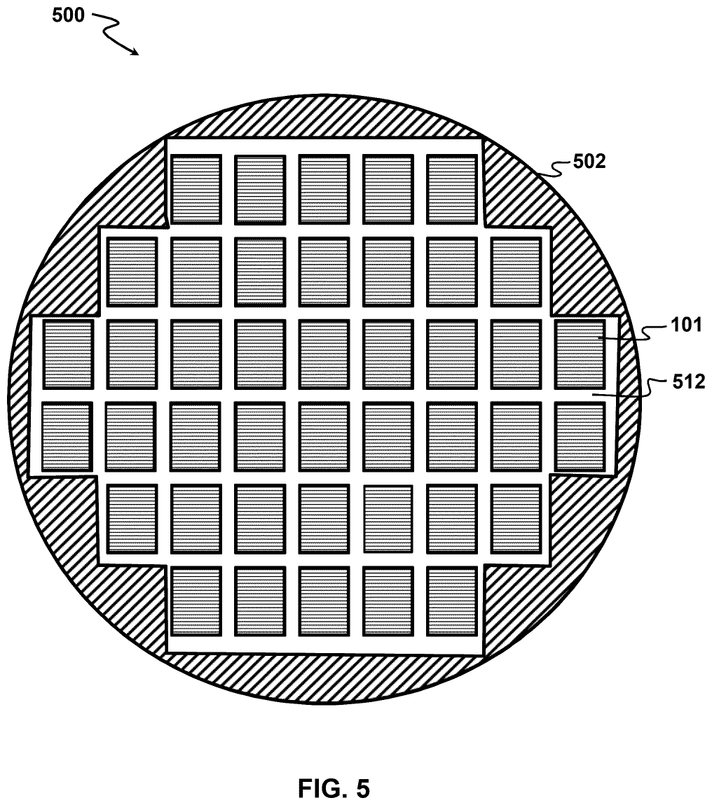

FIG. 5 is a top-down view of a reconstituted wafer 500 similar to that shown in FIG. 4, but with a through-hole wafer gap filler 512 according to an aspect of the present disclosure. As the name suggests, the through-hole wafer gap filler includes holes 503 which are configured, e.g., sized and shaped, to accept diamond dies 501. The dimensions of the holes may be chosen to snugly fit the diamond dies. Alternatively, the dimensions of the diamond dies may be slightly smaller than that of the holes to provide enough clearance that the dies fit easily into the holes. An adhesive material or filler may be placed around diamond dies in the holes to further stabilize the diamond die and gap filler assembly.

FIG. 6 is a side cut-away view showing a method for making a reconstituted wafer product with a through hole gap filler wafer 512 according to an aspect of the present disclosure. In this implementation, a logic-side wafer 502 may be coated in a logic-side diamond bond layer 510A which is compatible with bonding to the diamond smoothening layer 508A. Additionally, the logic-side diamond bond layer 510A may be compatible with bonding to the through-hole gap filler wafer 512. In some implementations the through-hole gap filler wafer may also be coated in smoothening material or bonding material compatible with bonding with the bonding layer 510A.

Next, according to some aspects of the present disclosure the through-hole filler wafer 512 may be bonded to the logic side wafer 502 with the bond layer 510A. Alternatively, the through-hole filler wafer 512 may be bonded to the logic side wafer 502 after the diamond dies have been bonded to the logic side wafer. Alternatively, the through-hole filler wafer 512 is not bonded, and may be removed (e.g. used repeatedly). The through-holes 503 of the gap filler wafer may be fitted over the diamond dies 501 allowing the filler wafer to make contact and bond with the bond layer 510A of the logic-side semiconductor wafer 502. The through-hole filler wafer 512 may be made from silicon, e.g., single crystal silicon, or ceramics, e.g., sapphire, or silicon carbide. The through-hole filler wafer 512 may be manufactured by removing material from a solid wafer, e.g., by electrical discharge machining, laser cutting, water jetting, or water-guided laser cutting.

As discussed above, the diamond dies 501 may have their logic-side bonding surfaces coated in a smoothening layer 508A. According to some aspects of the present disclosure an adhesion layer may be disposed on the diamond bonding surface prior to the creation of the smoothening layer to improve adhesion of the smoothening layer with the diamond die. Shown here the bottom of the diamond die 501 is the bonding surface for the logic side and may be rough. The smoothening material 508A may fill and even out the rough surface making it suitable for bonding. More commonly, the smoothening material is smoothened after deposition, e.g., by polishing or grinding. The diamond dies 501 may then be fitted into the through-holes 503 of the filler wafer 512. Sufficient pressure and heat may be applied to the diamond dies to bond to the logic side wafer 502 with the bond layer 510A along with the through-hole filler wafer 512 according to the selected compatible bonding method as will be discussed below. Alternatively, the diamond dies 501 may be fit into the through-holes 503 of the filler wafer 512. The smoothening layer 510A may then be applied to the diamond die and filler wafer assembly. The assembly may then be bonded to the logic side wafer 502 with the logic side bond layer 510A. In some implementations after bonding the diamond dies to the logic side wafer, the logic side wafer may be thinned to less than 10 or less than 100 microns in thickness. A temporary carrier may be adhered to the logic side wafer to improve stability for subsequent bonding steps. The temporary carrier may be removed after completion of the product.

After the diamond dies and filler wafer are bonded, a smoothening layer 508B may be applied to the heat sink side bonding surface of diamond dies 501 (shown here as the top) and the through-hole filler wafer 512. Alternatively, the smoothening layer 508B may be applied to the heatsink side of the diamond die prior to placement of the diamond dies in the through-holes of the filler wafer. In such cases the through-hole filler wafer may be bonded to the heatsink side semiconductor wafer 504 without the smoothening layer.

Prior to bonding with the diamond die and through-hole filler wafer assembly, the heatsink side wafer 504 may have a heatsink-side diamond bond layer 510B applied to the diamond bonding side of the wafer. The heatsink side wafer diamond bond layer may be a material that is compatible with bonding to the smoothening layer 508B and, in some implementations, the bare filler wafer 512. After application of the bond layer 510B, the heatsink-side wafer 504 with bond layer may be attached to the resulting diamond die and filler wafer assembly by application of sufficient pressure and heat according to the selected compatible bonding method as will be discussed below.

In some alternative implementations the diamond dies which are coated with a smoothening material may be bonded to the heat sink side wafer and the filler wafer may be bonded to the logic side wafer. The heatsink-side wafer and diamond die assembly may then have the diamond die porting inserted into the through-holes of the filler wafer and sufficient bonding pressure and heat applied to attach the two assemblies according to the chosen bonding method as discussed below. Thus, may be created a reconstituted wafer product with a through hole gap filler wafer.

Dicing of the bonded pair of the IC (logic) wafer to the reconstituted diamond wafer may happen after bonding. Dicing of the bonded pair may be based on stealth dicing, plasma dicing, laser dicing, or saw dicing, or a combination. Dicing may happen in one step, or multiple steps, e.g., first dicing through the IC wafer from one side, and subsequently dicing the reconstituted diamond wafer from the opposite side. Dicing through the full thickness of, e.g., the heat sink side wafer, may happen in steps, e.g., by adding grooves or cracks into the wafer prior to assembling the reconstituted wafer, or prior to bonding the reconstituted wafer to the IC (logic) wafer. Similarly, thinning of the heat sink side wafer 504 may happen prior to bonding to the IC (logic) wafer, or after bonding to the IC (logic) wafer.

Additionally, some implementations may require less packaging for the diamond dies. For example and without limitation, the diamond dies may be packaged bare on tape on reel or tape on frame assemblies. The diamond surfaces may be polished, or rough. The diamonds may be coated with a smoothening layer on top and/or bottom side. The smoothening layer may have been smoothened by polishing. The heat sink side of the diamond may be bonded to thick copper foil. The copper foil may be coated with silicon or bonded to silicon. The diamonds may be coated by the precursor to a thermally conductive, compliant material for bonding, e.g. a solder, eutectic, or the precursor to transient liquid phase bonding (TLPB).

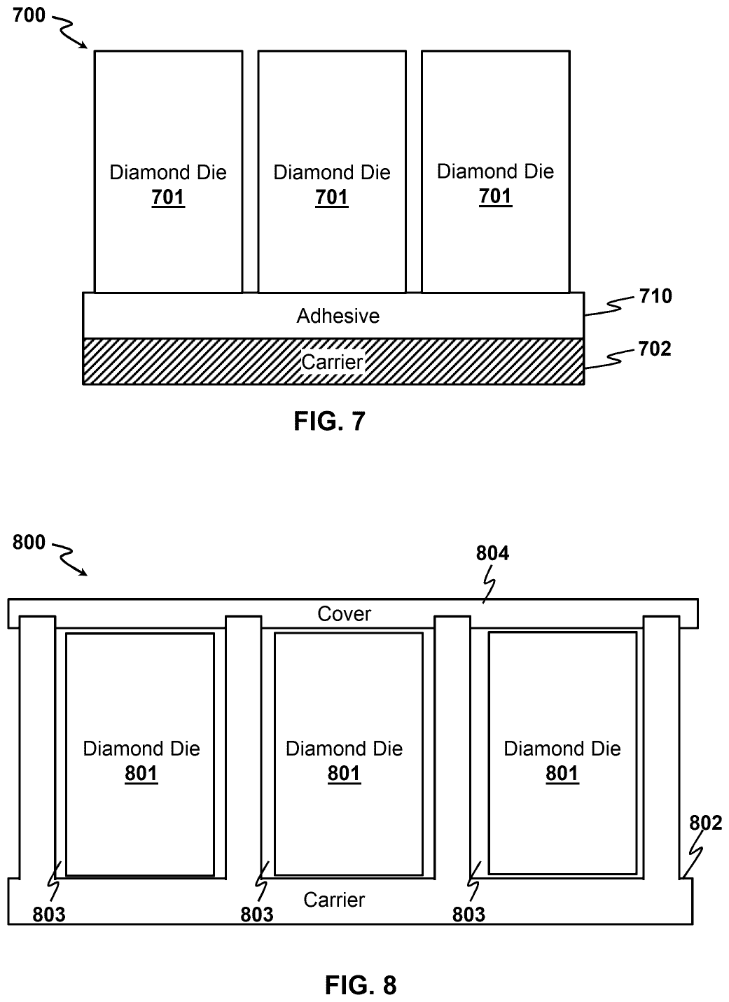

FIG. 7 depicts a side cut-away view of a reconstituted wafer 700 having polished diamond dies 701 on a carrier 702 such as a tape in frame or film frame according to an aspect of the present disclosure. In the implementation shown, the diamond dies 701 may be polished (for example less than 5 nanometers (nm) average surface roughness and less than 5 microns thickness variation) for ease of use. Alternatively, the diamond dies 701 may have an unfinished roughness from production (for example and without limitation, between 100 nm and 300 nm average surface roughness and a thickness variation of between 5 microns and 30 microns), or a lapped finish (for example between 5 nm and 100 nm average surface roughness and less than 5 microns of thickness variation). An adhesive layer 710 may be applied to a carrier. The polished diamond dies 701 may then be attached to the carrier 702 with the adhesive layer 710. The carrier here may be flexible tape made from a material such as polyolefins, PVC, polyurethanes, or UV-curable tapes for film frame (tape in frame). Alternatively, the carrier 702 may be a rigid material for example and without limitation, a temporary semiconductor or glass wafer. The adhesive layer 710 may be a layer of temporary adhesive such as for example and without limitation a UV curing adhesive tape or a solvent curing adhesive, or pressure sensitive adhesive, or a thermoplastic material. The temporary adhesive such as UV cure adhesive may provide for easy removal of the diamond die from the carrier by exposure of the adhesive to the curing agent e.g. UV radiation of the appropriate wavelength. Alternatively, a permanent adhesive may be used and in which case the permanent adhesive and carrier would have to be removed by destructive methods such as grinding and/or polishing.

FIG. 8 depicts a tape on reel delivery of diamond dies 801 with cover tape 804 according to aspects of the present disclosure. As shown in this implementation the carrier substrate 802 includes multiple cavities 803 for diamond dies. The diamond dies 801 may be inserted into the cavities 803 and then covered with the cover tape 804. The carrier substrate 802 may be made from a flexible material for example and without limitation paper, or a plastic such as polycarbonate or polystyrene. Similarly the cover tape may be made from a flexible material suitable for covering the diamond dies and attaching to dividers of the carrier. The cover tape may be made from for example and without limitation a heat activated plastic or a pressure sensitive adhesive with backing plastic.

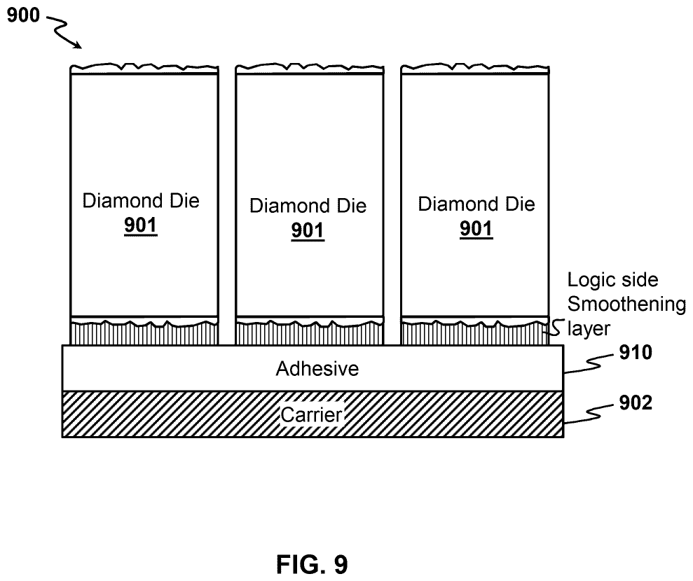

FIG. 9 depicts another implementation of reconstituted wafer 900 without gap filler according to aspects of the present disclosure. Here, the diamond dies 901 have at least one side coated with a smoothening layer 908. In some implementations the surfaces of the diamond dies on which the smoothening layer will be applied may be coated with an adhesion layer to improve the attachment of the smoothening layer to the diamond dies. The carrier may be any suitable rigid material for example in some implementations the carrier may be the logic-side wafer or the heatsink-side wafer. The carrier may be coated with an adhesive material. The adhesive material may be a UV curing adhesive, solvent curing adhesive, pressure sensitive adhesive, a thermoplastic material, or in some implementations adhesive material may correspond to a bond layer material as discussed above. The smoothening layer may then be attached to the adhesive. In implementations where the adhesive is a bond layer the smoothening layer may be permanently bonded to the carrier using the appropriate bonding method for the smoothening layer and bonding layer materials. As shown this implementation may omit the deposited gap filler material or gap filler wafer as it may provide for easier removal from carrier and/or better suit requirements of the user.

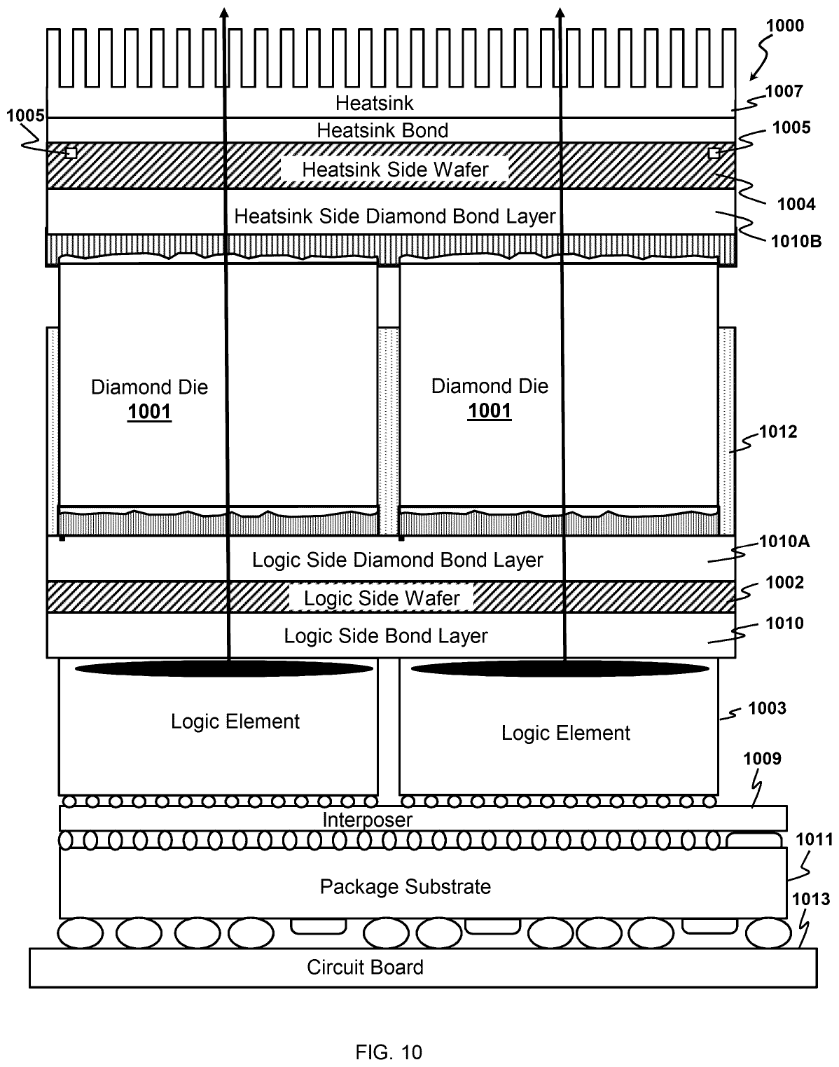

FIG. 10 shows a reconstituted wafer heat spreader product 1000 incorporated into a Chip on Wafer on Substrate (CoWoS) system stack according to an aspect of the present disclosure. As shown in this implementation the logic-side wafer 1002 of the product 1000 is bonded to logic elements 1003 with a logic-side bond layer 1010. In some implementations, the heat spreader product 1000 may be fabricated using a diamond substrate coated with a precursor to a thermally conductive bond material where the thermally conductive bond material is compliant during bonding to a semiconductor device. The thermally conductive bond material may have thermal conductivity higher than 10 W/m-K after bonding. The bond material may contain lead, tin, indium, bismuth, zinc, or cadmium or combinations thereof. In some implementations, the bond material may be a eutectic or a transient liquid phase bond material. The precursor may contain copper, aluminum, gold, silver, nickel, silicon, germanium, lead, tin, indium, bismuth, zinc, or cadmium or combinations thereof.

The logic elements 1003 may be any circuit device that produces heat for example and without limitation, transistors, switches, resistors, inductors, lasers, diodes, capacitors, voltage regulators, integrated circuit devices, central processing units (CPUs), graphics processing units (GPUs), tensor processing units (TPUs), neural processing units (NPUs), application specific circuits (ASICs), AI chips, system on chip (SoC), field programmable gate arrays (FGPAs), memory devices, such as random access memory (RAM), static RAM (SRAM), dynamic RAM (DRAM), read-only memory (ROM), volatile memory, etc. The logic-side bond layer 1010 may be any material suitable to create a heat conductive interface between one or more logic elements and the logic side wafer. In some implementations the logic side bond layer 1010 may be an adhesive or bonding material. In alternative implementations the bond layer may be omitted or may be a heat conductive material and the heat spreader product 1000 may be held in contact with the logic elements 1003 by a fastener or housing for the CoWoS system. In some implementations each entire logic element or a portion of each logic element may correspond to a hot-spot in a larger integrated circuit device. Thus, the placement of the diamond dies 1001 may correspond closely with the location of these hotspots. For example, the diamond dies may be selectively placed to reduce the distance the heat must travel before reaching a diamond die, thus limiting the spread of heat in the likely heat sensitive logic element 1003. The diamond dies may be attached to the logic-side wafer 1002 by a logic-side diamond bond layer 1010A. Similarly the diamond dies 1001 may be attached to the heatsink-side wafer 1004 by a heatsink-side diamond bond layer 1010B. Gaps between adjacent diamond dies 1001 may be fully or partially filled with gap filling material 1012.

The heat sink side wafer 1004 and/or logic side wafer 1002 may include one or more alignment marks 1005 or fiducials as shown. The alignment marks may be deposited onto the semiconductor wafer and/or etched into the semiconductor wafer to aid in the placement and alignment of the diamond dies. Alignment mark size, shape, location, material etc., may differ depending upon the chosen alignment system and/or the bonding material(s) chosen. For example and without limitation an alignment system which uses Infrared (IR) detection for alignment may be incompatible with copper bond layers as it reflects IR radiation. In some implementations, the logic side wafer and/or heat sink side wafer may include an alignment feature, such as a D-cut or V-notch to facilitate alignment with other wafers during subsequent processing.

Additionally as shown the heat sink side wafer of the product may be bonded to a heatsink 1007 with a heatsink bond layer 1014, e.g., a metal thermal interface material. The heatsink bond layer may be any material suitable to create a heat conductive interface between one or more heatsinks and the heatsink side wafer 1004. In some implementations the logic side bond layer 1010 may be an adhesive or bonding material. In alternative implementations the heatsink bond layer 1014 may be omitted or is a heat conductive material and the heat spreader product 1000 may be held in contact with the logic elements by a fastener or housing for the CoWoS system. The heatsink here may be any material or device having sufficient size, properties and/or configuration to absorb and/or carry heat away from the CoWoS system with heat spreader product. For example and without limitation the heatsink 1007 may be, a larger heat conductive surface (e.g. a metal surface), a finned heat conductive surface (e.g. air cooling finned heat sink), heat conductive surface with heat pipes, a heat conductive surface with one side exposed to a second moving heat conductive medium (e.g. water cooling heat sink), or a heat conductive surface exposed to a heat conductive medium which changes phase (e.g. phase change cooling, and evaporative cooling). The cooling (heat sinking) may happen by air cooling, vapor chambers, heat pipes, liquid cooling, spray cooling, immersion cooling, etc.

In the implementation shown, the logic elements 1003 are part of a larger integrated circuit device. The logic elements may be communicatively coupled with an interposer 1009. The communicative coupling may be for example and without limitation, through solder connections (e.g. micro solder bumps) or conductive contact pins. The interposer may include conductive vias and lateral conductive traces to make communicative connections between different elements within the CoWoS stack. The interposer 1009 may be communicatively coupled with a package substrate 1011. The communicative coupling to the package substrate may be for example and without limitation, through solder connections (e.g. solder bumps) or conductive contact pins. The package substrate may include conductive vias and lateral conductive traces to make communicative connections between different elements connected to the package substrate within the CoWoS stack. The package substrate 1011 may be communicatively coupled with a circuit board 1013. The communicative coupling to the circuit board may be for example and without limitation, through solder connections (e.g., solder balls) or conductive contact pins. The circuit board may include conductive vias and lateral conductive traces to make communicative connections between different elements connected to the circuit board within the CoWoS stack.

It should be noted that prior to affixing the logic side wafer 1002 to the logic elements 1003 the logic side wafer may be thinned to <100 μm or <10 μm. Likewise the prior to affixing the heatsink-side wafer 1004 to the heatsink 1007, the heatsink-side wafer may be thinned. Similarly, the heatsink-side wafer may be thinned to <500 μm, <100 μm or <10 μm. Generally it may be favorable for the logic side wafer 1002 to be thinner than heatsink 1004 side wafer as it is closer to the heat generating elements, e.g., the logic elements 1003. It should further be understood that if the thinned wafers are extremely thin a temporary carrier may be adhered to the wafer that is first thinned to improve stability for thinning the second wafer, the temporary carrier may subsequently be removed before bonding.

Wafer thinning may be accomplished, for example and without limitation, by using one or more of the following techniques: abrasive techniques, grinding, lapping, chemical mechanical polishing (CMP), polishing (wet or dry), wet etching, dry etching, or laser ablation. The thinning process may be facilitated by, e.g., a temporary carrier with a temporary adhesive, specialized pads or tapes, or the TAIKO process. Instead of temporary carriers with temporary adhesives, mobile electrostatic carriers might be used. Furthermore, buried layers may be introduced into the wafers that facilitate thinning to below 10 μm, e.g. to 500 nanometers, or even to 10's nanometers. These buried layers may act as an etch stop, e.g. as used for thinning in backside power delivery processes, may facilitate laser debond, e.g. similar to EVG's IR layer release, or may facilitate film transfer similar to Soitec's SmartCut.

While the implementation depicted in FIG. 10 may represent a CoWoS system it should be understood that aspects of the present disclosure are not so limited and may be implemented in any type of integrated circuit device packaging system including but not limited to 2D, 2.1D, 2.5D, other 3D, and 3.5D packaging systems. As used herein, “2D packaging” refers to a traditional method of packaging semiconductor devices where one or multiple integrated circuits (ICs) or chips are mounted side-by-side on a single (organic laminate) packaging substrate, such as a printed circuit board (PCB), without stacking them vertically. The components are arranged in a single plane, forming a two-dimensional layout. “2.5D packaging” refers to a packaging technique in which multiple integrated circuit chips (sometimes called “dies”) are placed side-by-side on a common interposer, e.g., silicon or an organic interposer, that provides high-density interconnections between the chips. The interposer sits on a packaging substrate. “2.1D packaging” refers to a packaging technique where a redistribution layer (RDL) is used instead of a silicon interposer . . . “3D packaging” refers to a packaging technology where multiple semiconductor dies (chips) are stacked vertically on top of each other within a single package and interconnects are made vertically between stacked dies, e.g., using through-silicon vias (TSVs) therefore offering a higher packaging density than 2D, 2.1D or 2.5D packaging. “3.5D packaging” refers to a packaging technique that uses a combination of vertically stacked dies and interposers.

The reconstituted wafer product may contain diamond dies with adhesion layers, diffusion barriers, smoothening layers, bonding layers, a wafer on the logic side, a wafer on the heat sink side, adhesion layers on one or both wafers, diffusion barriers on one or both wafers, bond layers on one or both wafers, or even smoothening layers on one or both wafers. In addition, the reconstituted wafer product may contain gap fillers. Furthermore, the reconstituted wafer product may contain perimeter sealants that partially or completely seal the materials sandwiched between both wafers from the outside, so there is no exposure to these materials during the wafer processing, e.g. cleaning, thin film deposition, film densification, film surface activation, bonding, annealing, thinning, lithography, bumping, and debonding temporary carriers. The sealants may be adhesives, sealants, molding compounds, polymers, thermoplastics, epoxies, photoresists, benzocyclobutene (BCB) derivatives, spin-on photo-dielectrics, silicones, or polyimides. Similarly, spin-on glass or polymer-derived ceramics may be used, e.g. polysilazane derivatives (e.g. polyborosilazane), polysiloxane derivatives, polysilane derivatives (e.g. polycarbosilane), polysilsesquioxanes, polysilsesquiazanes, polysilylcarbodiimides, etc.

### Bond Layers

The material of the bond layers depends partly on the bonding technique that is used and requirements of the fab that receives the reconstituted wafers. For example, some fabs prefer to avoid exposed metals, such as copper. The bond layers may be deposited on the wafers, and may be deposited on the diamond dies, e.g. on the smoothening layers.

By way of example, and not by way of limitation, Copper (Cu) may be used as a bonding layer material in thermal compression bonding (TCB) on one or both wafers, and as a smoothening layer on the diamond dies. Both copper and tin (Sn) may be used for transient liquid phase bonding (TLPB), e.g. tin stacked on top of copper on one or both wafers, and copper on the diamond dies. Similarly, instead of copper, either nickel, or gold, or silver may be used in this TLPB example, or instead of tin, indium (In) may be used. A solder may be used as a bonding and/or smoothening layer and/or compliant material in solder bonding on one or both wafers, either applied as a film (coating), pre-form (foil), wire, or paste, e.g. SAC305, or high-temperature Sn—Pb alloys may be used. A eutectic may be used as a bonding and/or smoothening layer and/or compliant material in eutectic bonding on one or both wafers, either applied as a film (coating), pre-form (foil), wire, or paste, e.g. Au—Si, Au—Ge, Au—Sn, or Cu—Sn. Other compositions of interest may be Zn, Zn—Sn (e.g. eutectic), or Zn—Al (e.g. eutectic). A brazing material may be used as a bonding and/or smoothening layer and/or compliant material in brazing bonding on one or both wafers, either applied as a film (coating), pre-form (foil), wire, or paste, e.g. Au—Ti, Al—Si, or Al—Zn alloys may be used. A sinter paste may be used as a bonding and/or smoothening layer and/or compliant material in sinter bonding on one or both wafers, dispensed or printed as a paste, e.g. silver paste or copper paste. A metal foil, e.g. copper or aluminum, optionally softened by annealing prior to or during bonding, may be used as a bonding and/or smoothening layer and/or compliant material during bonding (e.g. TCB) with one or both wafers, and one or both wafers optionally metallized, and the diamond dies optionally metallized, with the metallization outer surface e.g. copper, or gold, or silver. A reactive multi-layer foil or film, e.g. repeating alternating layers of aluminum and nickel, optionally softened by annealing prior to or during bonding, may be used as a bonding and/or smoothening layer and/or compliant material during bonding (e.g. TCB) with one or both wafers, and one or both wafers optionally metallized, and the diamond dies optionally metallized, with the metallization outer surface e.g. copper, or gold, or silver, or titanium, or chromium. These reactive multi-layer foils or films may be initiated by a heat pulse, laser pulse, electric spark, or other means, and this initiation may result in a self-sustaining exothermic reaction raising the local temperature to aid bonding, and may produce intermetallic compounds. Other multi-layer materials may be aluminum with titanium, or titanium with amorphous silicon. Silicon may be used as a bonding layer material and/or smoothening material in surface activated bonding (SAB) or atomic diffusion bonding (ADB). Dielectrics may be used as bonding layer and/or smoothening layer materials in plasma assisted bonding (PAB) or fusion bonding. Metals, e.g. metal foils (e.g. aluminum, zinc, solder, eutectic), may be heated to the melting point to aid bonding, or may be heated to soften without melting to aid in bonding. Adhesive bonding may be used. Adhesives may be, without limitation, silver-filled epoxies, curable thermal interface materials, e.g. based on carbon nanotubes, or graphene.

Bonding diamond dies, e.g. rough SCD, to wafers, e.g. single crystal silicon wafers, may be performed by surface melting the silicon wafer while pressing the diamond dies into the soft (e.g. liquid) silicon surface. The silicon wafer surface may be heated through the silicon wafer by adding an absorbing layer onto the silicon surface, e.g. a doped silicon surface. The silicon wafer surface may be heated through the diamond, e.g. with visible lasers that are transmitted through the diamonds, yet get absorbed by (undoped) silicon. The silicon surface may be heated with a laser, by rapid thermal processing (RTP), e-beam heating, inductive heating, LFA, PulseForge, etc. The laser may be a kW IR laser (e.g. CO₂), or a kW visible laser. By way of example, and not by way of limitation, rough SCD dies may be bonded to the logic side wafer by silicon surface melting, and subsequently the heat sink side wafer may be attached to the diamond dies via a thick copper foil between the dies and the heat sink side wafer.

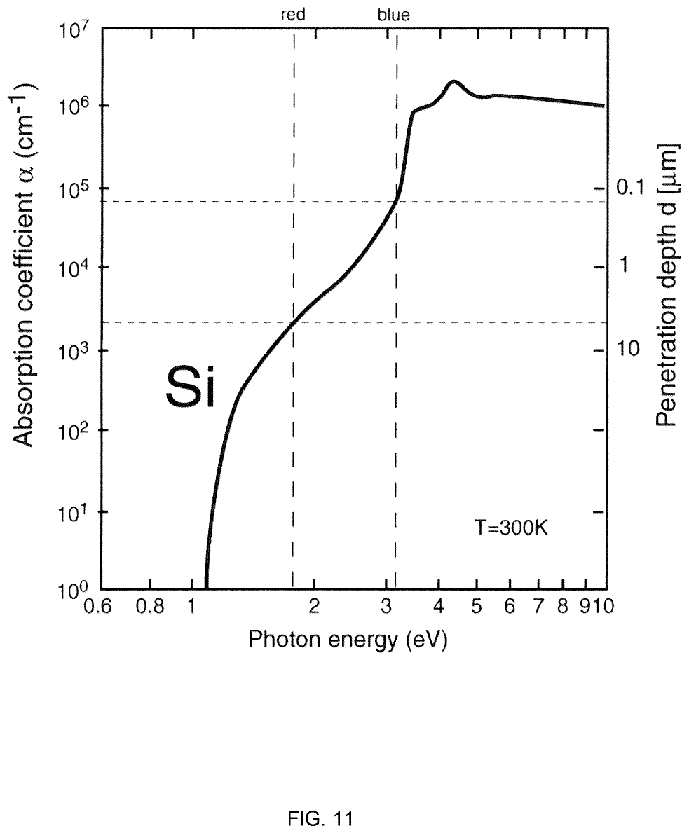

High intensity lasers may be used to illuminate—through the diamond—the interface between the diamond and silicon to heat, melt, and cause joining. Kilowatt and multi-kilowatt lasers may be used to illuminate and heat very large areas. A highly polished diamond may not be required as the high thermal conductivity of diamond may ensure that the interface temperature is kept uniform. Ideal wavelengths for heating silicon may be shorter than 1.1 micrometer, and ideally much shorter, e.g. 550 nm to 350 nm, where there are a range of fiber and fiber delivered lasers available that can deliver large, square or rectangular, spots (e.g., from Nuburu, Laserline, or Trumpf). According to the graph shown in FIG. 11, the absorption depth for these shorter wavelength lasers may be on the order of ˜100 nm compared to many microns near 1000 nm, ensuring that the interaction volume of the laser, silicon/diamond interface may be kept highly localized and efficient.

In an alternative method of bonding diamond to silicon wafers according to aspects of the present disclosure, a nickel metal interface may be used. A layer of nickel may be deposited between the diamond and silicon, and then the assembly may be annealed, creating two interfaces: one where nickel may form a Ni—C bond with the diamond, and another where it may form a Ni—Si bond with the silicon. The goal of this method may be promoting interdiffusion at both interfaces, resulting in a robust and durable bond. This implementation may involve depositing a controlled thickness of nickel onto either the diamond or silicon wafer, followed by the placement of the opposing material. The assembly may then be subjected to an annealing process at temperatures between 750 C and 1200 C. During annealing, the nickel may facilitate the formation of a strong chemical bond with both the diamond and the silicon. The interdiffusion between the Ni—C and Ni—Si interfaces may enhance the overall strength and stability of the bond, making this method particularly useful for applications where a durable, high-temperature-resistant bond between diamond and silicon may be required. Alternatively, instead of nickel, titanium, or chromium may be used.

The thermal conductivity of copper (foil) and its alloys may range from 80 W/m-K to 400 W/m-K (e.g., pure copper) depending on the alloy composition, and microstructure, the latter impacted by manufacturing method, and additional processing. Annealing copper (foil) may improve thermal conductivity and soften the foil for temperatures of e.g., 300 Celsius up to its melting point. Copper may be deposited as a thin film, e.g., by electroplating, electroless plating, e-beam deposition, or sputtering with a thermal conductivity close to the copper bulk thermal conductivity (˜400 W/m-K). Additionally, copper may be introduced as a thin foil with a thermal conductivity in the range of 80 W/m-K to 400 W/m-K. Furthermore, copper may be introduced as a paste followed by sintering with a thermal conductivity after sintering as high as 300 W/m-K.

The thermal conductivity of aluminum (foil) and its alloys may range from 80 W/m-K to 237 W/m-K (e.g. pure aluminum) depending on the alloy composition, and microstructure, the latter impacted by manufacturing method, and additional processing. Annealing aluminum (foil) may improve thermal conductivity and soften the foil for temperatures of e.g. 300 Celsius up to its melting point. Aluminum may be deposited as a thin film, e.g. by e-beam deposition, and sputtering with a thermal conductivity close to the aluminum bulk thermal conductivity (˜237 W/m-K). Additionally, aluminum may be introduced as a thin foil with a thermal conductivity in the range of 80 W/m-K to 237 W/m-K.

The thermal conductivity of silicon may range from 1 W/m-K to 140 W/m-K. Amorphous silicon films may have thermal conductivities of ˜1 W/m-K, whereas polycrystalline silicon (films) may have thermal conductivities around 50 W/m-K. and single crystal silicon as high as 140 W/m-K, albeit heavily dependent on doping, and crystal defect concentration. Silicon may be introduced as an amorphous film, polycrystalline film, single crystal wafer, polycrystalline wafer, or as a powder. Silicon introduced as a powder may be used as gap-filler, or may be used between one or both waters and the diamond dies. Silicon powder may be sintered or fused together by a heat source, e.g. by laser annealing.

Materials like titanium and chromium may be deposited by physical vapor deposition. Materials like copper, tin, zinc, gold, and silver may be deposited as a film by physical vapor deposition or plating, e.g. electroplating or electroless plating.

The placement and bonding of diamond dies to form the reconstituted wafer product may be performed by sequential dies to wafer (SD2W) bonding, or collective dies to wafer bonding (CD2W). The bonding of the second wafer, e.g., heatsink-side wafer, may be a separate bonding step after the SD2W or CD2W bonding. Alternatively, the diamond dies may be placed onto the first wafer, and the second wafer is placed onto the diamond dies, and the whole stack may be bonded by temperature and/or force in one step.

ADB and SAB are generally performed between ultrasmooth layers, e.g., silicon with a roughness (Sa) of less than 0.5 nanometers. A silicon smoothening layer may be deposited or otherwise formed on the surfaces of the diamond dies and, in some implementations, the gap filler prior to bonding. The silicon smoothening layer may be formed by thin film deposition followed by smoothening, e.g., CMP. The silicon smoothening layer may be amorphous, nanocrystalline, microcrystalline, or polycrystalline. Deposition of the silicon layer may be by any known method for example and without limitation, Physical Vapor Deposition (PVD) or chemical vapor deposition (CVD). In the SAB process the respective bonding surfaces are cleaned of contaminants, e.g., organics, metals, and particles, prior to entering the ultra-high-vacuum environment. The bonding surfaces are treated with beams of atoms or ions in an ultra-high-vacuum (UHV) environment to remove remaining contaminants (e.g., organics, metals, and oxides) and create reactive dangling bonds and typically amorphize a few nanometers of each bonding surface (1-5 nm). Typically, Argon atoms or ions are used. Amorphizing the bonding surfaces avoids potential issues with lattice mismatch. The treated surfaces are then subject to bonding pressure (force) under UHV. The UHV environment allows for a few minutes to bring surfaces into contact and form strong (e.g. covalent) bonds. The bonding may be done at relatively low temperature, e.g., in the range of room temperature (about 25° C.). The resulting bonds are free of a significant thickness of intermediate material. As a result of the amorphization, there may be an interface region of amorphous material between the bulk crystalline silicon wafer and the silicon smoothening layer with an interface between the two amorphous materials. In some implementations SAB may be used to bond a polished diamond die to one or more of the silicon wafers without a smoothening layer and/or bond layer. SAB may be used to form a reconstituted wafer product based on one or two silicon wafers bonded to diamond dies, e.g. smoothened diamond dies with silicon smoothening layers. The silicon may be deposited by CVD, and smoothened by CMP.

In ADB, the bonding surfaces are cleaned and UHV thin films (e.g., 1-5 nm) of metal (e.g., Ti) or semiconductor (e.g., Si or AlN) or oxide are formed on the bonding surfaces e.g., by sputtering of atoms, ions, neutral species, or clustered species. The thin films may be amorphous or crystalline films. Because the films are freshly created in UHV they bond together very effectively by bringing the surfaces into contact with each other and subjecting them to little or no pressure (force) and minimal/no heating. The resulting structure has at least two interfaces, one between the wafer and an interfacial bonding layer and another between the interfacial bonding layer and the smoothening layer. ADB equipment is commercially available, e.g., from Canon Anelva Corporation of Kanagawa, Japan. ADB may be used to form a reconstituted wafer product based on one or two silicon wafers bonded to diamond dies, e.g. smoothened diamond dies with silicon smoothening layers. The silicon may be deposited by CVD, and smoothened by CMP. The thin films used for bonding may be titanium, silicon or an oxide.

Plasma-assisted bonding (PAB) of silicon substrates is commonly used in CMOS foundries for advanced packaging, e.g. hybrid bonding, with process temperatures from 150° C. to 400° C. PAB bonding is very mature for wafer to wafer bonding. Furthermore, PAB may not require ultra-high vacuum. These are all benefits of PAB. However, the PAB bond relies on dielectric films (e.g. SiO₂ or SiCN) with a very low thermal conductivity (˜1 W/m-K) resulting in a relatively high thermal barrier resistance despite the relatively low film thickness of 100's nanometers. Thus, there may be a need to reduce the thermal resistance for PAB by further thinning the bond layers and/or increasing the thermal conductivity of these bond layers. Furthermore, PAB has strict roughness requirements (e.g. Sa<0.5 nm). PAB may be used to form a reconstituted wafer product based on one or two silicon wafers bonded to diamond dies, e.g., smoothened diamond dies with silicon or dielectric smoothening layers. The thin films used for bonding may be silicon oxide, silicon nitride, silicon carbon-nitride, or similar dielectrics. The smoothening and bonding films may be deposited by CVD, and smoothened by CMP.

Thermo-compression bonding (TCB) historically is mainly used for vertical interconnects and perimeter sealing (e.g., MEMS) with silicon at temperatures of 300° C. to 500° C. and requires significant force (e.g., 10's MPa). Typical bond line thickness for TCB is in the micrometer range (e.g. 1-10 micrometers). TCB's roughness requirements are less strict (e.g., Sa<3 nm). Process temperature and force in TCB may be reduced by improved smoothness, flatness, and cleanliness of the metal surfaces. Improved smoothness, flatness, and cleanliness may also allow for thinner films. Furthermore, coefficient-of-thermal expansion (CTE) matching of the diamond and wafers may allow a further thickness reduction of the metal films. As such, the similar CTE for silicon and diamond may be very beneficial for a further (bond) film thickness reduction when silicon wafers are used to build the reconstituted wafer product. Common materials used for metal bonding are gold and copper. Process temperature and force reduction may allow for fragile stacks (e.g., avoiding device, lateral or vertical interconnect damage), compatibility with temporary adhesives, alignment accuracy improvement, reduced warpage, reduced thermal stress, etc. TCB is a form of metal bonding that involves solids only. TCB may be used to form a reconstituted wafer product based on one or two silicon wafers bonded to diamond dies, e.g., smoothened diamond dies with copper smoothening layers. Copper may be deposited by plating onto e.g. titanium and/or nickel deposited by PVD onto the diamond dies, and the copper may be smoothened by CMP. The bond layer on the wafers may be copper with an adhesion layer (e.g. titanium), and a diffusion barrier layer (e.g. titanium nitride, nickel, etc.) between the silicon wafer and the copper. A copper foil in a range of 50 micrometers to 750 micrometers may be sandwiched between the diamond dies and the heat sink side wafer. Alternatively, a foil of aluminum may be sandwiched between the diamond dies and the heat sink side wafer. The aluminum foil may be coated, e.g. with an adhesion layer, diffusion barrier layer, and copper. Instead of a metal foil, dies or wafers of silicon carbide may be used. The silicon carbide may be coated, e.g., with an adhesion layer, diffusion barrier layer, and copper. Instead of copper for smoothening and bonding, aluminum films may be used.

In some implementations the smoothing layer may be omitted by using solders and/or eutectics with process (liquification) temperatures above 300° C. Metal bonding that involves a liquid includes solder bonding, eutectic bonding, and transient liquid phase bonding (TLPB). These liquid-based forms of metal bonding have the added benefit of further lowering temperature (e.g., 180° C. to 300° C.) and force requirements (e.g., <1 MPa), and reduced roughness requirements (e.g. Sa<100 nm). In addition, organic or polymer bonding involves deposition of a precursor, molecule, monomer, oligomer, or polymer on one or two surfaces followed by bonding. This implementation may require only metallization of the wafer (e.g., Ti/Ni) and diamond die (e.g., Ti), with no smoothening layers. Deposition by dispensing, pre-forms, printing. Example materials for this process may be for example and without limitation lead-containing eutectics, solders, and/or brazing materials of the Pb—Ag, Pb—Sn—Ag, Pb—In—Ag. Zn, Zn—Sn, and Zn—Al family. Some non-limiting examples include Pb90Sn5Ag5, Pb95.5Sn2Ag2.5, Pb90In5Ag5, Pb95Ag5. Other examples of TLPB bonding materials include tin or indium containing materials for example, without limitation, Cu—Sn, Ni—Sn, Au—Sn, Ag—Sn, Ag—In, and Au—In. TLPB may be used to form a reconstituted wafer product based on one or two silicon wafers bonded to diamond dies. Copper may be deposited by plating onto e.g., titanium and/or nickel deposited by PVD onto the diamond dies, and subsequently tin may be plated over the copper. The bond layer on the wafers may be copper with an adhesion layer (e.g., titanium), and a diffusion barrier layer (e.g., titanium nitride, nickel, etc.) between the silicon wafer and the copper. Optionally, tin may be plated over the copper on the silicon wafer. A copper foil in a range of 50 micrometers to 750 micrometers may be sandwiched between the diamond dies and the heat sink side wafer. Alternatively, a foil of aluminum may be sandwiched between the diamond dies and the heat sink side wafer. The aluminum foil may be coated, e.g., with an adhesion layer, diffusion barrier layer, and copper. Instead of a metal foil, dies or wafers of silicon carbide may be used. The silicon carbide may be coated, e.g., with an adhesion layer, diffusion barrier layer, and copper.

Sintering may be also used to bond the surfaces. A silver sintering paste, gold sintering paste or copper sintering paste may be applied as the bond layer. Sufficient heat and pressure may be applied at the bonding surface to cause the sintering paste to form a bond with the sintering paste. For example and without limitation, sintering with copper paste may be used. Sintering may be done at temperatures below 250° C., either with minimal force (<1 MPa), or high force (e.g. >10 MPa). The final bond line thickness may be 50 microns, or 10 microns. The sintered layer may be porous or dense. The sintered layer may have a thermal conductivity over 100 W/m-K, even over 150 W/m-K. Sintering may be used to form a reconstituted wafer product based on one or two silicon wafers bonded to diamond dies. Copper, or silver, or gold may be deposited by plating onto, e.g., titanium and/or nickel deposited by PVD onto the diamond dies. Copper, or silver, or gold may be deposited with an adhesion layer (e.g., titanium), and a diffusion barrier layer (e.g., titanium nitride, nickel, etc.) between the silicon wafer and the copper, or silver, or gold. A sintering paste, e.g., silver paste, may be placed between the silicon wafer and the diamond dies. A copper foil in a range of 50 micrometers to 750 micrometers may be sandwiched between the diamond dies and the heatsink-side wafer. Alternatively, a foil of aluminum may be sandwiched between the diamond dies and the heat sink side wafer. The aluminum foil may be coated, e.g., with an adhesion layer, diffusion barrier layer, and copper, silver, or gold. Instead of a metal foil, dies or wafers of silicon carbide may be used. The silicon carbide may be coated, e.g., with an adhesion layer, diffusion barrier layer, and copper, silver, or gold.

In implementations using adhesives the adhesive material may be any material suitable for adhering the two surfaces together. Some examples include without limitation, pressure sensitive adhesives, UV curing adhesives, thermoplastics, solvent curing adhesives, carbon-nanotube filled adhesives, graphene filled adhesive, brewerBOND material, waferBOND material etc. These adhesives may be permanent (permanent bonding) or removed (temporary bonding) during manufacturing using the appropriate removal technique for the type of temporary adhesive. Curing of the adhesives (e.g., cross linking) may be based on heat, irradiation (e.g., UV), or water for adhesives, or based on cooldown for thermoplastic materials. The thickness of the organic bond line may be 100 nanometers, or as thin as 5 nanometers. Deposition may be performed by spin coating, spraying, dipping, or jetting. Materials may be epoxies, photoresists, benzocyclobutene (BCB) derivatives, spin-on photo-dielectrics, silicones, or polyimides. Similarly, spin-on glass or polymer-derived ceramics may be used, e.g., polysilazane derivatives (e.g. polyborosilazane), polysiloxane derivatives, polysilane derivatives (e.g. polycarbosilane), polysilsesquioxanes, polysilsesquiazanes, polysilylcarbodiimides, etc. These materials may be filled with nano-sized materials with a high thermal conductivity (and lower CTE), e.g. diamond nanopowder, aluminum nitride (AlN) nanopowder, silicon nitride (SiNₓ) nanopowder, beryllium oxide (BeO) nanopowder, aluminum oxide (Al₂O₃) nanopowder, graphite, carbon nanotubes, graphene, etc.

Temporary bonding may be used in multiple steps during the processing. Temporary bonding may be used for thinning the wafers. Temporary bonding may be used with thinning the heatsink side wafer. The thinned logic side wafer may be placed onto the temporary carrier prior to thinning the heatsink side wafer. The temporary carrier may be made of glass, silicon, quartz, or silicon carbide. The temporary carrier may match in CTE with the bonded wafer or dies. The temporary carrier may have through holes, e.g., to aid in chemical or solvent debonding. The temporary carrier may be optically transparent, e.g., to aid in optical debonding. The temporary carrier may support electrostatic bonding and debonding. The temporary carrier may contain a buried layer or surface layer that supports optical debonding. The temporary adhesive may be organic. The temporary adhesive may cross-link or be a thermoplastic. The temporary adhesive may contain one coating, or more than one coating. One of these coatings may absorb light, e.g., laser, UV, or pulsed light, which aids in debonding. The temporary carrier may have alignment marks. The temporary carrier may be bonded by a permanent bonding method, e.g., SAB, ADB, PAB, or TCB. The temporary bonding may be accomplished by a mobile electrostatic carrier. The final removal of the temporary carrier may be based on (visible or IR) laser debonding, UV debonding, thermal (slide) debonding, chemical debonding, (thermo-)mechanical debonding, (thermal) solvent debonding, electrostatic debonding, or abrasive and/or chemical removal of the temporary carrier.

In some implementations bonding may utilize a multi-layer thermally reactive foil that provides instantaneous or extremely rapid heating. Such a reactive multi-layer foil may be fabricated by vapor-depositing thousands of alternating nanoscale layers of Aluminum (Al) and Nickel (Ni). When activated by a small pulse of local energy from electrical, optical or thermal sources, the foil reacts exothermically to precisely deliver localized heat up to temperatures of 1500° C. in fractions (thousandths) of a second. By way of example, and not by way of limitation, an Al—Ni multi-layer thermally reactive foil is sold commercially under the name NanoFoil® by Indium Corporation of Clinton New York. Nanofoil® is a registered trademark of Thermal Conductive Bonding, Inc. of Sacramento, California. Other foil compositions may be boron-titanium, aluminum-titanium, and titanium-silicon. In addition to the energetic multi-layer material other materials may be included in the stack that specifically melt, comply with surfaces, and react with the wafers or diamond dies to be bonded.

### Gap Filler

The gap filler material may be a depositable material or a through-hole gap filler wafer as discussed above. The gap filler material preferably has a Coefficient of Thermal Expansion (CTE) matched closely with both Si and the die containing diamond and some stiffness to support ultrathin silicon between the dies containing diamond. Additionally it is desirable that the gap filler material is a material suitable for dicing by traditional dicing means (e.g., saw, laser, or plasma dicing) and when fully filling the gaps easily planarized. Some implementations may use gap fillers such as and without limitation: spin-on-glass (SOG), machined silicon through-hole wafer, low-CTE polyimide (2-3 ppm/C), borosilicate or silica glass in sol-gel form (3-5 ppm/C), or glass powder filled adhesives/polymers, polybenzimidazole (5 ppm/C). Additionally, in some implementations, the gap filler may help with avoiding edge rounding when smoothening the smoothening layer (e.g. CMP).

### Smoothening Layer

It is often economically desirable to be able to use diamond dies with surfaces that are not perfectly smooth and with a relaxed thickness tolerance in a reconstituted wafer product. In such cases, a smoothening layer may be formed on the surface(s) of the diamond dies to accommodate for imperfections in the diamond die surface(s). The smoothening layer may deal with surface roughness, but also with dimensional (thickness) tolerances (e.g., bow, warp, flatness, total thickness variation (TTV), or target thickness). The smoothening layer allows the reconstituted wafer product to use incoming rough diamond dies with a broad range in dimensional (thickness) and roughness tolerances. After smoothening (e.g. CMP) the smoothening layer, the surfaces are smooth, and the dimensional (thickness) tolerances are tight.

Smoothening layers (either of microns thickness with high thermal conductivity, or 10's to 100's nanometers when low thermal conductivity) may include but are not limited to: Copper (plated, e.g. 15 micrometer with thermal conductivity close to 400 W/m-K), silicon (polycrystalline/microcrystalline by hot CVD of microns thickness and thermal conductivity ˜50 W/m-K, or amorphous silicon by colder CVD when 10's to 100's nanometers and thermal conductivity ˜1 W/m-K). Note here that smoothening layers may be applied to the bonding surfaces of the diamond dies and may be excluded from the gaps in between the diamond dies. The bonding surfaces of the diamond dies may be lapped and, in some implementations, polished appropriately for the chosen bonding method. For example and without limitation application of an amorphous or nanocrystalline silicon smoothening layer may be suitable to smoothen a lapped diamond die surface whereas application of a polycrystalline silicon smoothening layer may be more suitable for a diamond die with a rougher surface and more relaxed thickness tolerances.

The thickness of the smoothening layer(s) depends on the roughness and thickness variation of the diamond die. The higher the thickness variation of incoming diamond die, the thicker the smoothening layer needs to be and the higher the thermal conductivity of the smoothening layer needs to be. The surface roughness and thickness variation of the diamond die depends on where in the diamond die fabrication process the diamond die is picked. In general terms, the further upstream one picks the diamond die from the wafering line, the rougher and larger the thickness variation and generally, the lower the cost of producing the diamond die. By way of example, and not by way of limitation, at certain early stages of diamond die fabrication, e.g., before lapping has been started or is complete, the diamond die surface may be rough, e.g., 100 nm to 300 nm mean surface roughness with high thickness variation Δt, e.g., 5 μm<Δt<30 μm. At an intermediate stage, e.g., after lapping is complete, the diamond die surface may be rough, e.g., less than 100 nm mean surface roughness with a tight thickness variation Δt, e.g., Δt<5 μm. At a later stage, the diamond die surface may be smooth, e.g., <5 nm roughness with a tight thickness variation Δt, e.g., Δt<5 μm.

The previous descriptions provide a non-limiting list of multiple permutations of smoothening layers, bond layers, diamond die surface finish, gap filler type, bond methods, and wafers for the reconstituted wafer heat spreader product and their suitability for bonding to integrated circuit device package types. The overall thickness of the reconstituted wafer product may vary. As a non-limiting example, the thickness of the reconstituted wafer product may be roughly 2,325 micrometers prior to thinning the logic side and heat sink side wafers and may be roughly 800 micrometers after thinning the logic side and heat sink side wafers. The final thickness may be the result of 300 micrometers thick diamond die, e.g. SCD, and 450 micrometers copper foil, in addition to 10 to 30 micrometers silicon on the logic side and heat sink side. The manufacturing of the reconstituted wafer product may start with full thickness wafers, e.g., 775 micrometers thick, 300 millimeters diameter silicon wafers, or may start with partially thinned wafers that are easily handled, e.g. 350 micrometers thick. Thus, aspects of the present disclosure represent a heat spreader product which may include one or more reconstituted wafers. The reconstituted wafer may provide structural stability to the product allowing for easier integration.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A”, or “An” refers to a quantity of one or more of the items following the article, except where expressly stated otherwise. The appended claims are not to be interpreted as including means-plus-function limitations, unless such a limitation is explicitly recited in a given claim using the phrase “means for.”

1. A reconstituted wafer product, comprising:
a plurality of dies containing diamond sandwiched between a first wafer and a second wafer in a manner that provides a thermally conductive connection between the first wafer and second wafer through the dies containing diamond.

2. The product of claim 1, wherein the thermal resistance of the reconstituted wafer product is lower than 2 mm²-K/W when integrated into a final chip package.

3. The product of claim 1, wherein the thermal resistance of the reconstituted wafer product is lower than 1 mm²-K/W when integrated into a final chip package.

4. The product of claim 1, wherein the thermal resistance of the reconstituted wafer product is lower than 0.5 mm²-K/W when integrated into a final chip package.

5. The product of claim 1, wherein the dies containing diamond include one or more single crystal diamond (SCD) dies.

6. The product of claim 5, wherein the dies containing diamond are all SCD dies.

7. The product of claim 5, wherein the one or more SCD dies are characterized by a lateral dimension of 1 centimeter or greater.

8. The product of claim 1, wherein the dies containing diamond include at least one polycrystalline diamond die.

9. The product of claim 1, wherein the dies containing diamond include at least one composite diamond die comprised of diamond and a metal, wherein the metal includes one or more of the following: copper, silver, gold, aluminum, and zinc.

10. The product of claim 1, wherein at least one of the dies containing diamond has a roughness on at least one side of at least 2 nanometers.

11. The product of claim 1, wherein first and second wafers are characterized by lateral dimensions corresponding to those of a standard-sized semiconductor wafer.

12. The product of claim 1, wherein the first and second wafers are silicon wafers.

13. The product of claim 1, wherein at least one of the first and second wafers is characterized by a thickness of less than 100 micrometers.

14. The product of claim 1, wherein at least one of the first and second wafers is characterized by a thickness of less than 10 micrometers.

15. The product of claim 1, wherein a layer of copper, aluminum, or silicon carbide is sandwiched between the dies containing diamond and a first wafer, wherein the copper, aluminum, or silicon carbide, is at least 100 micrometers thick.

16. The product of claim 1 wherein the dies containing diamond are attached to either: the first wafer, the second wafer, or both wafers by either: thermocompression bonding, soldering, eutectic bonding, transient liquid phase bonding, sintering, surface activated bonding, atomic diffusion bonding, plasma assisted bonding, brazing, or adhesive bonding.

17. The product of claim 1 wherein the at least one side of each of the dies containing diamond is coated with a smoothening material.

18. The product of claim 17 wherein the smoothening material is a metal and the dies containing diamond are attached to either: the first wafer, the second wafer or both wafers, by thermocompression bonding or adhesive bonding.

19. The product of claim 1 wherein either: the first wafer, the second wafer, or both wafers are silicon wafers bonded to the dies containing diamond by surface melting the silicon wafers.

20. The product of claim 19 wherein the dies containing diamond each have a mean surface roughness on at least one side of at least 2 nanometers, and one or both wafers are silicon wafers and wherein the silicon wafers are bonded to the dies containing diamond by surface melting the silicon wafers.

21. The product of claim 1 wherein either: the first wafer, the second wafer, or both wafers are bonded to the dies containing diamond with a multi-layer material made out of nickel and aluminum, aluminum and titanium, or titanium and silicon.

22. The product of claim 1 further comprising a smoothening material coupled to each of the plurality of dies containing diamond, wherein the smoothening material is a semiconductor smoothening layer and the dies containing diamond are attached to either: the first wafer, the second wafer, or both wafers by either: surface activated bonding, atomic diffusion bonding, plasma assisted bonding, or adhesive bonding.

23. The product of claim 17 wherein the smoothening material is a dielectric and the dies containing diamond are attached to either: the first wafer, the second wafer, or both wafers by either: plasma assisted bonding, surface activated bonding, atomic diffusion bonding, or adhesive bonding.

24. The product of claim 1, wherein the dies containing diamond are attached to either: the first wafer, the second wafer, or both wafers using a bond material.

25. The product of claim 24, wherein the bond material includes copper, silicon, or a dielectric.

26. The product of claim 1, wherein gaps between adjacent dies containing diamond of the plurality of dies containing diamond are partially or completely filled with a gap-filling material.

27. The product of claim 26, wherein the gap-filling material includes spin-on-glass.

28. The product of claim 26, wherein the gap-filling material includes a through-hole wafer.

29. The product of claim 26, wherein the gap-filling material includes one or more of the following: a sol-gel, oxide powder, silicon powder, thermoplastic, curable adhesive, molding compound, epoxies, photoresists, benzocyclobutene (BCB) derivatives, spin-on photo-dielectrics, silicones, polybenzimidazole, and polyimides.

30. The product of claim 1, wherein either: the first wafer, the second wafer, or both wafers are between 10 micrometers and 100 micrometers thick.

31. The product of claim 1, wherein either: the first wafer, the second wafer, or both wafers are less than 10 micrometers thick.

32. The product of claim 1 wherein at least one of the plurality of dies containing diamond are located in an area of the reconstituted wafer product corresponding to a hot spot in one or more logic elements when the reconstituted wafer product is bonded with the one or more logic elements.

33. The product of claim 1, wherein at least one of the plurality of dies containing diamond is located in an area of the reconstituted wafer product corresponding to the location of one or more logic elements that are known good dies when the reconstituted wafer product is bonded with the one or more logic elements.

34. The product of claim 1 further comprising one or more dummy dies sandwiched between the first and second wafer wherein the dummy dies are placed on locations corresponding to one or more logic elements that are not known good dies when the reconstituted wafer product is bonded with the one or more logic elements.

35. A reconstituted wafer product, comprising:
a plurality of dies containing diamond attached to a tape in frame or temporary carrier substrate or tape on reel carrier substrate.

36. The product of claim 35, wherein the dies containing diamond include one or more SCD dies.

37. The product of claim 36, wherein each of the dies containing diamond are SCD dies.

38. The product of claim 35, wherein at least one of the one or more dies is characterized by a lateral dimension of 1 centimeter or greater.

39. A reconstituted wafer product, comprising:
a plurality of dies containing diamond attached to a wafer in a manner that provides a thermally conductive connection between the wafer and the dies containing diamond;
a first smoothening layer formed on a first side of the plurality of dies containing diamond between the wafer and the plurality of dies containing diamond; and
a second smoothening layer formed on a second side of the plurality of dies containing diamond, wherein the plurality of dies containing diamond is sandwiched between the first smoothening layer and the second smoothening layer.

40. The product of claim 39, wherein one or more dies in the plurality of dies containing diamond are characterized by a mean surface roughness of 2 nanometers to 1000 nanometers for at least one surface of the dies containing diamond prior to deposition of the smoothening layer.

41. The product of claim 39, wherein one or more dies in the plurality of dies containing diamond are characterized by a thickness variation of between 5 micrometers and 30 micrometers prior to deposition of the smoothening layer.

42. The product of claim 39, wherein at least one of the first and second smoothening layers provides a thickness variation of less than 5 micrometers.

43. The product of claim 39, wherein at least one of the first and second smoothening layers provides a mean surface roughness of less than 5 nanometers for at least one surface.

44. The product of claim 39 further comprising one or more dummy dies attached to the wafer wherein the dummy dies are placed on locations corresponding to one or more logic elements that are not known good dies when the reconstituted wafer product is bonded with one or more logic elements.

45. A diamond heat spreader product, comprising: a die containing diamond coated with a precursor to a thermally conductive bond material where the thermally conductive bond material is compliant during bonding to one or more logic elements.

46. The product of claim 45, wherein the thermal conductivity of the thermally conductive bond material is higher than 10 W/m-K after bonding.

47. The product of claim 45, wherein the die containing diamond has a mean surface roughness higher than 2 nanometers for at least one surface.

48. The product of claim 45, wherein the bond material includes at least one of the following: lead, tin, indium, bismuth, zinc, and cadmium.

49. The product of claim 45, wherein the bond material is a eutectic or a transient liquid phase bond material.

50. The product of claim 45, wherein the precursor includes at least one of the following: copper, aluminum, gold, silver, nickel, silicon, germanium, lead, tin, indium, bismuth, zinc, and cadmium.
